(19) United States
(12) Patent Application Publication
(10) Pub. No.: US 2026/0202711 A1
(43) Pub. Date: Jul. 16, 2026

(54) DISPLAY DEVICE COMPRISING MIRROR DISPLAY COMPOSED OF PLURALITY OF LAYERS, AND CONTROL METHOD THEREFOR

(71) Applicant: Samsung Electronics Co., Ltd., Suwon-si (KR)

(72) Inventors: Seungki CHO, Suwon-si (KR); Yongseok JANG, Suwon-si (KR)

(73) Assignee: Samsung Electronics Co., Ltd., Suwon-si (KR)

(21) Appl. No.: 19/567,043

(22) Filed: Mar. 14, 2026

Related U.S. Application Data
(63) Continuation of application No. PCT/KR2024/015179, filed on Oct. 7, 2024.

(30) Foreign Application Priority Data
Oct. 6, 2023 (KR) 10-2023-0133703

(51) Int. Cl. G02F 1/17; G06F 3/01; G09G 3/3225; G09G 3/36

(52) U.S. Cl. CPC G02F 1/17; G06F 3/011; G09G 3/3225; G09G 3/3648; G09G 2320/0613; G09G 2354/00; G09G 2360/144

(57) ABSTRACT

A display device including a mirror display including a black layer with adjustable transmittance, a transparent display layer, arrangeable on the front surface of the black layer so as to display an image, and a mirror layer, arrangeable on the front surface of the transparent display layer, with adjustable reflectivity; and one or more processors to adjust the transmittance of the black layer and the reflectively of the mirror layer according to a current operation state of the display device from among a plurality of operation states of the display device, and controlling whether to display an image on the transparent display layer.

### CROSS-REFERENCE TO RELATED APPLICATION

This application is a continuation application, under 35 U.S.C. §111(a), of international application No. PCT/KR2024/015179, filed October 7, 2024, which claims priority under 35 U. S. C. §119 to Korean Patent Application No. 10-2023-0133703, filed October 6, 2023, the disclosures of which are incorporated herein by reference in their entireties.

### BACKGROUND

### 1. Field

The disclosure relates to a display device and a control method therefor, and more particularly, to a display device including a mirror display composed of a plurality of layers, and a control method therefor.

### 2. Description of Related Art

Fueled by development of electronic technologies, various types of electronic apparatuses are being developed and distributed. In particular, recently, various types of electronic apparatuses including TVs are being used in general homes. These electronic apparatuses have been gradually equipped with various functions according to users’ demands.

As an example, various types of services can be provided through a mirror display providing both of a mirror function and a display function. For example, a mirror display can reflect a user, and at the same time, can display a virtual object with which the user can interact.

In particular, a mirror display can be utilized as an indoor interior prop, and there has been a demand for a method that enables control of a mirror display to operate as glass, a mirror, or a display device according to the user’s intent or circumstance.

### SUMMARY

A display device according to an embodiment of the disclosure for achieving the aforementioned purpose includes a mirror display including a black layer with adjustable transmittance, a transparent display layer arrangeable on a front surface of the black layer and displays an image, and a mirror layer, arrangeable on a front surface of the transparent display layer, with adjustable reflectivity, and at least one processor configured to adjust the transmittance of the black layer and the reflectively of the mirror layer according to a current operation state of the display device among a plurality of operation states of the display device, and control whether to display the image through the transparent display layer.

A control method for a display device including a mirror display according to an embodiment of the disclosure includes adjusting transmittance of a black layer and reflectivity of a mirror layer included in the mirror display according to a current operation state of the display device among a plurality of operation states, and controlling whether to display an image of a transparent display layer included in the mirror display, and the mirror display includes the black layer with adjustable the transmittance, the transparent display layer arrangeable on a front surface of the black layer and displays the image, and the mirror layer arrangeable on a front surface of the transparent display layer with adjustable reflectivity.

According to an embodiment of the disclosure for achieving the aforementioned purpose, in a computer-readable recording medium including a program executing a control method for a display device including a mirror display, the control method for a display device includes adjusting transmittance of a black layer and reflectivity of a mirror layer included in the mirror display according to a current operation state of the display device among a plurality of operation states, and controlling whether to display an image of a transparent display layer included in the mirror display, and the mirror display includes the black layer with adjustable transmittance, the transparent display layer arrangeable on a front surface of the black layer and displays the image, and the mirror layer arrangeable on a front surface of the transparent display layer with adjustable reflectivity.

### BRIEF DESCRIPTION OF THE DRAWINGS

FIG. 1 is a diagram illustrating characteristics of a mirror display according to an embodiment of the disclosure;

FIG. 2 is a block diagram illustrating a configuration of a display device according to an embodiment of the disclosure;

FIG. 3 is a diagram for illustrating configurations of each of a plurality of layers according to an embodiment of the disclosure;

FIG. 4 and FIG. 5 are diagrams for illustrating an operation of a mirror layer according to an embodiment of the disclosure;

FIG. 6 is a diagram for illustrating a configuration of a mirror display according to an embodiment of the disclosure;

FIG. 7 is a diagram for illustrating a first operation state of a display device according to an embodiment of the disclosure;

FIG. 8 is a diagram for illustrating a second operation state of a display device according to an embodiment of the disclosure;

FIG. 9 is a diagram for illustrating a third operation state of a display device according to an embodiment of the disclosure;

FIG. 10 is a diagram for illustrating an operation state of a display device according to an image according to an embodiment of the disclosure;

FIG. 11 is a diagram for illustrating an operation state of a display device according to an image according to an embodiment of the disclosure;

FIG. 12 is a diagram for illustrating an operation state of a display device that detects a user according to an image according to an embodiment of the disclosure; and

FIG. 13 is a flow chart for illustrating a control method for a display device according to an embodiment of the disclosure.

### DETAILED DESCRIPTION

Hereinafter, the disclosure will be described in detail with reference to the accompanying drawings.

As terms used in the embodiments of the disclosure, general terms that are currently used widely were selected as far as possible, in consideration of the functions described in the disclosure. However, the terms may vary depending on the intention of those skilled in the art who work in the pertinent field or previous court decisions, or emergence of new technologies, etc. Also, in particular cases, there may be terms that were designated by the applicant on his own, and in such cases, the meaning of the terms will be described in detail in the relevant descriptions in the disclosure. Accordingly, the terms used in the disclosure should be defined based on the meaning of the terms and the overall content of the disclosure, but not just based on the names of the terms.

In addition, in this specification, expressions such as “have,” “may have,” “include” and “may include” denote the existence of such characteristics (e.g.: elements such as numbers, functions, operations, and components), and do not exclude the existence of additional characteristics.

Further, the expression “at least one of A and/or B” should be interpreted to mean any one of “A” or “B” or “A and B.”

Also, the expressions “first,” “second” and the like used in this specification may be used to describe various elements regardless of any order and/or degree of importance. Further, such expressions are used only to distinguish one element from another element, and are not intended to limit the elements.

Meanwhile, the description in the disclosure that one element (e.g.: a first element) is “(operatively or communicatively) coupled with/to” or “connected to” another element (e.g.: a second element) should be interpreted to include both the case where the one element is directly coupled to the another element, and the case where the one element is coupled to the another element through still another element (e.g.: a third element).

Also, singular expressions include plural expressions, unless defined obviously differently in the context. In addition, in the disclosure, terms such as “include” or “consist of” should be construed as designating that there are such characteristics, numbers, steps, operations, elements, components, or a combination thereof described in the specification, but not as excluding in advance the existence or possibility of adding one or more of other characteristics, numbers, steps, operations, elements, components, or a combination thereof.

Further, in the disclosure, “a module” or “a part” performs at least one function or operation, and may be implemented as hardware or software, or as a combination of hardware and software. In addition, a plurality of “modules” or “parts” may be integrated into at least one module and implemented as at least one processor (not shown), except “a module” or “a part” that needs to be implemented as specific hardware.

Also, in this specification, the term “user” may refer to a person who uses an electronic apparatus or an apparatus using an electronic apparatus (e.g.: an artificial intelligence electronic apparatus).

Hereinafter, an embodiment of the disclosure will be described in more detail with reference to the accompanying drawings.

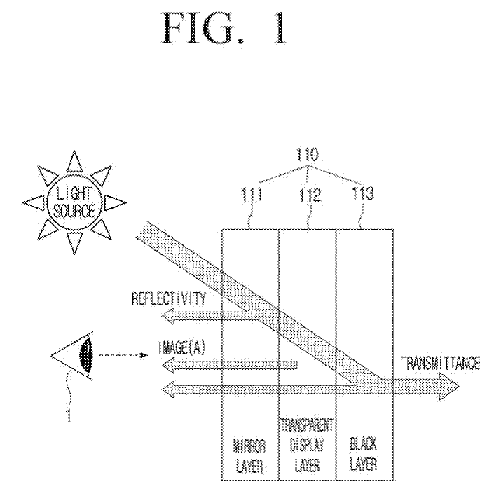

FIG. 1 is a diagram illustrating characteristics of a mirror display according to an embodiment of the disclosure.

A display device 100 according to an embodiment of the disclosure may be implemented as various types of mirror display devices that are installed in various places wherein a mirror is needed, and can transmit information while providing a mirror function. Here, ‘a mirror display’ is a compound word from ‘a mirror’ meaning a mirror and ‘display’ meaning a task of visually expressing information.

As illustrated in FIG. 1, the display device 100 includes a mirror display 110, and the mirror display 110 may include a plurality of layers 111, 112, 113.

As an example, the mirror display 110 may include a mirror layer 111, a transparent display layer 112, and a black layer 113.

For example, the mirror display 110 may include a black layer 113 wherein transmittance can be adjusted, a transparent display layer 112 which is arranged on the front surface of the black layer and displays an image, and a mirror layer 111 which is arranged on the front surface of the transparent display layer and wherein reflectivity can be adjusted.

According to an embodiment, the mirror layer 111 may be implemented as a glass plate or a transparent plastic plate on which a metal thin film or a dielectric multilayer film that reflects a part of incident light quantity, and transmits another part is deposited, and provide a mirror function.

According to an embodiment, the transparent display layer 112 may be referred to as a display panel, but for the convenience of explanation, it will be generally referred to as a transparent display layer 110 providing a display function.

According to an embodiment, the transparent display layer 112 may include a display including self-luminous diodes, or non-self-luminous diodes and a backlight. For example, the transparent display layer 112 may be implemented as various forms of displays such as a liquid crystal display (LCD), an organic light-emitting diodes (OLED) display, light-emitting diodes (LED), micro LED, mini LED, a plasma display panel (PDP), a quantum dot (QD) display, quantum dot light-emitting diodes (QLED), etc.

According to an embodiment, the self-luminous diodes, or the non-self-luminous diodes included in the transparent display layer 112 may be transparent diodes. For example, the transparent display layer 112 may include OLED wherein both of an anode and a cathode are implemented to be transparent according to a principle that metal thinner than predetermined thickness (e.g., 10nm) becomes transparent. According to an embodiment, the transparent display layer 112 may have high light transmittance (or, transmissivity) (e.g.: transmittance of greater than or equal to 70%) in a wavelength range of 380nm to 780nm.

According to an embodiment, the black layer 113 may be implemented as a glass plate or a transparent plastic plate on which a metal thin film or a dielectric multilayer film that reflects a part of incident light quantity, and absorbs another part is deposited, and provide a cover function.

For example, the black layer 113 may provide a cover function of blocking (or, absorbing) transmission of light that the transparent display layer 112 output for providing an image (A), or provide a glass function of transmitting light that the transparent display layer 112 output to the rear surface of the display device 100.

In the disclosure, for the convenience of explanation, the location of the user 1 will be defined as the front surface of the display device 100, as illustrated in FIG. 1.

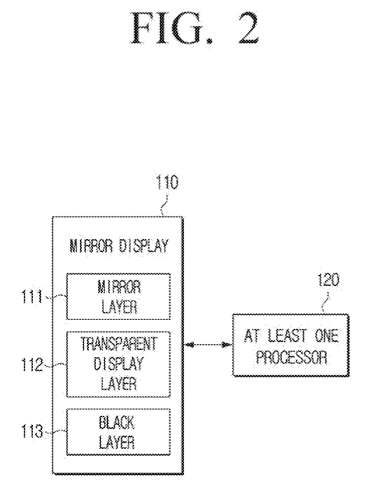

FIG. 2 is a block diagram illustrating a configuration of a display device according to an embodiment of the disclosure.

According to FIG. 2, the display device 100 includes a mirror display 110 including a mirror layer 111, a transparent display layer 112, and a black layer 113, and at least one processor 120.

Inside the transparent display layer 112 according to an embodiment of the disclosure, a driving circuit that may be implemented in forms such as an a-si TFT, a low temperature poly silicon (LTPS) TFT, an organic TFT (OTFT), etc., and a backlight and the like may be included.

According to an embodiment, if the transparent display layer 112 includes a backlight, the backlight may be implemented as an edge-type backlight such that light that the transparent display layer 112 output for providing the image (A) is incident onto the black layer 113.

Here, the edge-type backlight is arranged on at least one side surface among a plurality of side surfaces of a light guide plate, and may output light toward the light guide plate. The light output by the edge-type backlight may be reflected forward to the center of the transparent display layer 112 through the light guide plate.

As an example, if the transparent display layer 112 includes a direct backlight, light output by the transparent display layer 112 for providing the image (A) is blocked by the direct backlight and cannot be incident onto the black layer 113, and thus the transparent display layer 112 may include an edge-type backlight.

According to an embodiment, on the front surface of the mirror display 110, a touch sensor that has a form such as a touch film, a touch sheet, a touch pad, etc. and detects touch operations is arranged, and may be implemented to detect various types of touch inputs. For example, the mirror display 110 may detect various types of touch inputs such as a touch input by a user hand, a touch input by an input device such as a stylus pen, a touch input by a specific electrostatic material, etc. Here, an input device may be implemented as an input device of a pen type that can be referred to as various terms such as an electronic pen, a stylus pen, an S-pen, etc. According to an embodiment, the mirror display 110 may be implemented as a flat display, a curved display, a flexible display that can be folded and/or rolled, etc.

The at least one processor 120 controls the overall operations of the display device 100. Specifically, the at least one processor 120 may be connected with each of the components of the display device 100, and control the overall operations of the display device 100.

The at least one processor 120 may perform the operations of the display device 100 according to the various embodiments by executing at least one instruction stored in the memory.

The at least one processor 120 may include one or more of a central processing unit (CPU), a graphics processing unit (GPU), an accelerated processing unit (APU), a many integrated core (MIC), a digital signal processor (DSP), a neural processing unit (NPU), a hardware accelerator, or a machine learning accelerator. The at least one processor 120 may control one or a random combination of the other components of the electronic apparatus, and perform an operation related to communication or data processing. Also, the at least one processor 120 may execute the at least one program or instruction stored in the memory. For example, the at least one processor 120 may perform the method according to one or more embodiments of the disclosure by executing the at least one instruction stored in the memory.

In case the method according to one or more embodiments of the disclosure includes a plurality of operations, the plurality of operations may be performed by one processor, or performed by a plurality of processors. For example, when a first operation, a second operation, and a third operation are performed by the method according to one or more embodiments, all of the first operation, the second operation, and the third operation may be performed by a first processor, or the first operation and the second operation may be performed by the first processor (e.g., a generic-purpose processor), and the third operation may be performed by a second processor (e.g., an artificial intelligence-dedicated processor).

The at least one processor 120 may be implemented as a single core processor including one core, or it may be implemented as one or more multicore processors including a plurality of cores (e.g., multicores of the same kind or multicores of different kinds). In case the at least one processor 120 is implemented as multicore processors, each of the plurality of cores included in the multicore processors may include internal memory of the processor such as cache memory, on-chip memory, etc., and a common cache shared by the plurality of cores may be included in the multicore processors. Also, each of the plurality of cores (or some of the plurality of cores) included in the multicore processors may independently read a program instruction for implementing the method according to one or more embodiments of the disclosure and perform the instruction, or the plurality of entire cores (or some of the cores) may be linked with one another, and read a program instruction for implementing the method according to one or more embodiments of the disclosure and perform the instruction.

In case the method according to one or more embodiments of the disclosure includes a plurality of operations, the plurality of operations may be performed by one core among the plurality of cores included in the multicore processors, or they may be performed by the plurality of cores. For example, when the first operation, the second operation, and the third operation are performed by the method according to one or more embodiments, all of the first operation, the second operation, and the third operation may be performed by a first core included in the multicore processors, or the first operation and the second operation may be performed by the first core included in the multicore processors, and the third operation may be performed by a second core included in the multicore processors.

In the embodiments of the disclosure, the processor may mean a system on chip (SoC) wherein at least one processor and other electronic components are integrated, a single core processor, a multicore processor, or a core included in the single core processor or the multicore processor. Also, here, the core may be implemented as a CPU, a GPU, an APU, a MIC, a DSP, an NPU, a hardware accelerator, or a machine learning accelerator, etc., but the embodiments of the disclosure are not limited thereto.

In particular, the at least one processor 120 according to an embodiment of the disclosure may adjust the transmittance of the black layer 113, and adjust the reflectivity of the mirror layer 111.

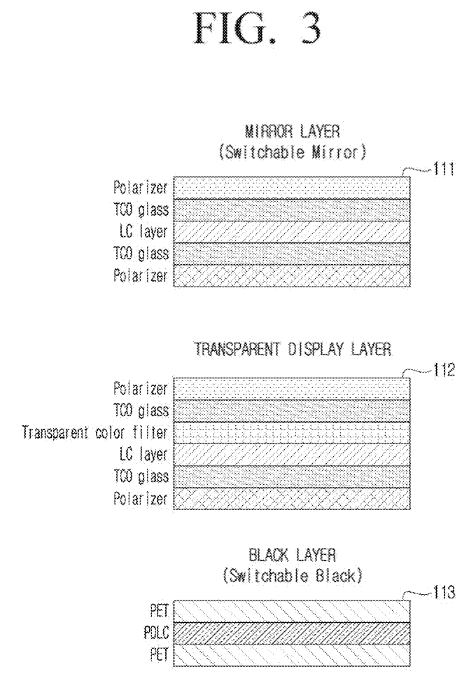

FIG. 3 is a diagram for illustrating configurations of each of a plurality of layers according to an embodiment of the disclosure.

The mirror layer 111 according to an embodiment of the disclosure may be implemented in a form of including a polarizer, upper glass, lower glass, and a reflective polarizer.

According to an embodiment, a liquid crystal (LC) layer may be formed between the upper glass and the lower glass. The liquid crystal (LC) is in an intermediate state between liquid and a crystal, and may thus have a structure wherein rod-shaped molecules (liquid crystal molecules) are aligned in one direction similarly to a solid crystal.

According to an embodiment, the polarizer may be implemented to transmit polarized light. As illustrated in FIG. 3, the upper glass and the lower glass may be implemented as transparent conductive oxide (TCO) glass, but are not limited thereto.

The transparent display layer 112 according to an embodiment of the disclosure may be implemented in a form of including a polarizer, upper glass, a liquid crystal display panel, lower glass, and a polarizer.

The liquid crystal display panel may include a transparent color filter and a liquid crystal (LC) layer.

According to an embodiment, if the transparent display layer 112 is implemented as an LCD, the transparent display layer 112 may include a backlight wherein a backlight lamp is arranged according to an edge method (i.e., an edge-type backlight).

The black layer 113 according to an embodiment of the disclosure may be implemented in a form of including an upper PET and a lower PET, and including a polymer dispersed liquid crystal (PDLC) between the upper PET and the lower PET.

According to an embodiment, the PDLC may maintain a transparent state or an opaque state according to whether electricity was applied according to control by the at least one processor 120.

For example, when electricity is applied, liquid crystal molecules inside the PDLC are arranged in one direction and transmit light, and thus the PDLC is maintained in a transparent state (referred to as a clear state (or, a glass state) hereinafter), and when electricity is not applied, liquid crystal molecules are arranged randomly and do not transmit light (or, scattering of light is generated), and the PDLC may be maintained in an opaque state (referred to as a black state hereinafter).

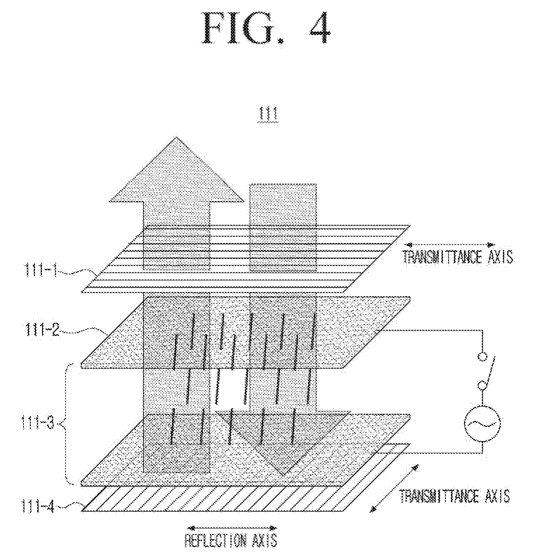

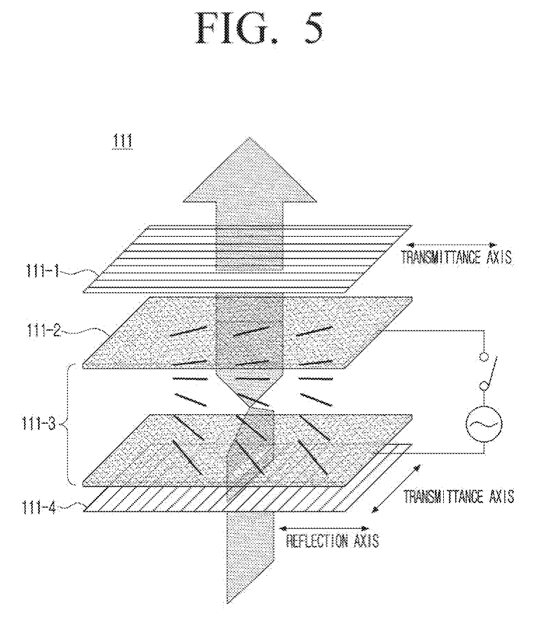

FIG. 4 and FIG. 5 are diagrams for illustrating an operation of a mirror layer according to an embodiment of the disclosure.

FIG. 4 illustrates the mirror layer 111 when the voltage is turned off, and when the voltage is turned off, the liquid crystal molecules maintain a vertical state, and incident polarized light may be transmitted through the liquid crystal layer 111-3 as it is, and reflected to a reflection axis of the reflective polarizer 111-5. Accordingly, the mirror layer 111 may be maintained in a mirror state.

For example, when electricity is not applied, incident polarized light is reflected to the reflection axis of the reflective polarizer, and thus the mirror function (referred to as a mirror state hereinafter) of the mirror layer 111 can be provided. Also, as illustrated in FIG. 5, when electricity is applied, incident polarized light rotates by 90 degrees and is transmitted through the reflection axis of the reflective polarizer 111-5, and thus the mirror layer 111 may be maintained in a transparent state (referred to as a clear state hereinafter).

Other than the above, depending on implementation examples, a protection film that performs a role of protecting the polarizer, a film that performs a role of classifying lights on the polarizer, etc. may be further included.

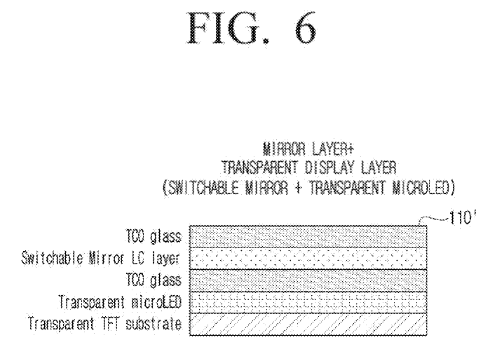

FIG. 6 is a diagram for illustrating a configuration of a mirror display according to an embodiment of the disclosure.

According to an embodiment of the disclosure, the mirror layer 111 and the transparent display layer 112 can obviously be implemented as a single layer.

For example, the single layer may be implemented in a form of including upper glass, lower glass, a liquid crystal (LC) layer (e.g., a switchable mirror LC layer) formed between the upper glass and the lower glass, a micro LED layer including transparent self-luminous diodes, and a transparent thin film transistor (TFT) substrate. However, this is merely an example, and the single layer is obviously not limited thereto.

Returning to FIG. 2, the at least one processor 120 according to an embodiment of the disclosure may control the display device 100 according to any one of a plurality of operation states. According to an embodiment of the disclosure, an operation state may also be referred to as an operation mode, but it will be generally referred to as an operation state for the convenience of explanation.

The at least one processor 120 according to an embodiment may adjust the transmittance of the black layer 113, and adjust the reflectivity of the mirror layer 111 according to the current operation state of the display device 100.

Also, the at least one processor 120 may control whether the transparent display layer 112 will display the image (A).

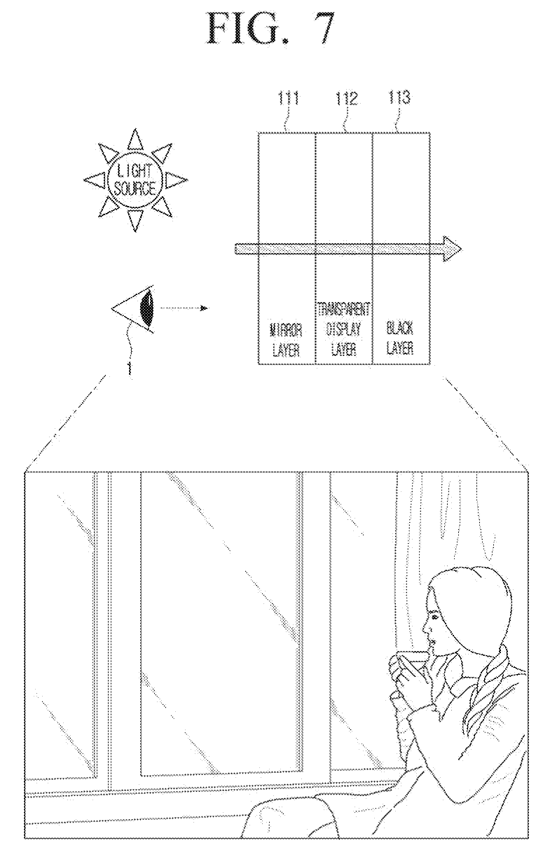

FIG. 7 is a diagram for illustrating a first operation state of a display device according to an embodiment of the disclosure.

Referring to FIG. 7, the at least one processor 120 according to an embodiment of the disclosure may, if the current operation state of the display device 100 is a first operation state, adjust the transmittance of the black layer 113 to maximum transmittance, and adjust the reflectivity of the mirror layer 111 to minimum reflectivity.

For example, the at least one processor 120 may apply power to the black layer 113, and apply power to the mirror layer 111.

Here, the maximum transmittance includes transmittance of greater than or equal to 70%, and the minimum reflectivity may include reflectivity of smaller than 20%. However, this is merely an example for the convenience of explanation, and they are obviously not limited to specific numbers.

As illustrated in FIG. 7, when the transmittance of the black layer 113 is adjusted to the maximum transmittance, the black layer 113 may be maintained in a clear state that is transparent like glass. Also, when the reflectivity of the mirror layer 111 is adjusted to the minimum reflectivity, the mirror layer 111 may be maintained in a clear state that is transparent like glass. According to an embodiment, the display device 100 may provide a glass function in the first operation state.

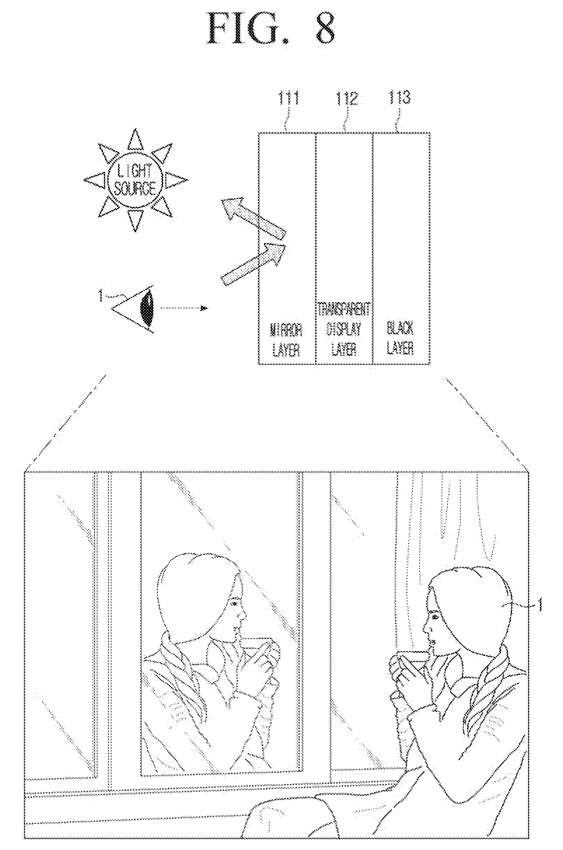

FIG. 8 is a diagram for illustrating a second operation state of a display device according to an embodiment of the disclosure.

Referring to FIG. 8, the at least one processor 120 according to an embodiment of the disclosure may, if the current operation state of the display device 100 is a second operation state, adjust the reflectivity of the mirror layer 111 to the maximum reflectivity. According to an embodiment, the at least one processor 120 may adjust the transmittance of the black layer 113 to the maximum transmittance, or adjust it to the minimum transmittance.

For example, the at least one processor 120 may not apply power to the black layer 113, and may not apply power to the mirror layer 111.

Here, the minimum transmittance of the black layer 113 may include transmittance of smaller than 20%, and the maximum reflectivity may include reflectivity of greater than or equal to 70%. However, this is merely an example for the convenience of explanation, and they are obviously not limited to specific numbers.

As illustrated in FIG. 8, when the reflectivity of the mirror layer 111 is adjusted to the maximum reflectivity, the mirror layer 111 may be maintained in a mirror state that provides a mirror phase corresponding to a user 1 located on the front side of the display device 100.

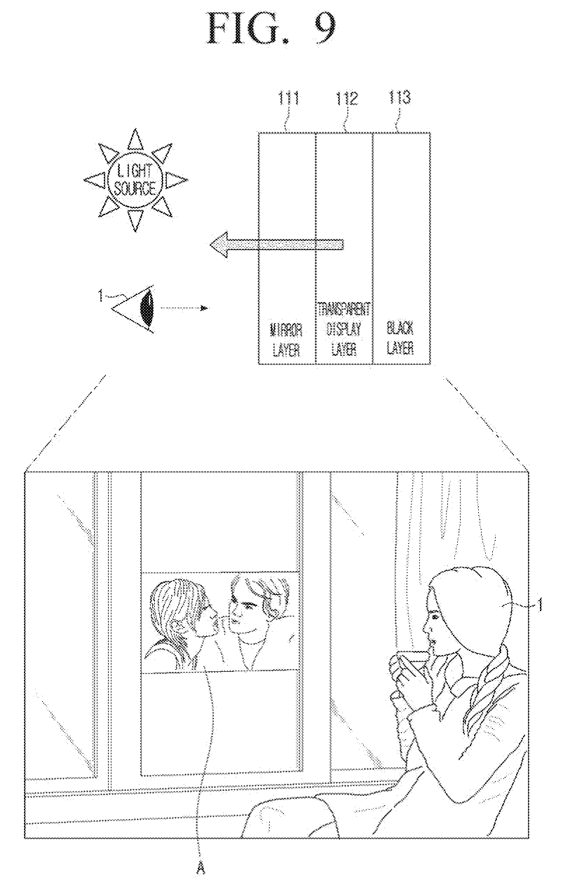

FIG. 9 is a diagram for illustrating a third operation state of a display device according to an embodiment of the disclosure.

Referring to FIG. 9, the at least one processor 120 according to an embodiment of the disclosure may, if the current operation state of the display device 100 is a third operation state, adjust the transmittance of the black layer 113 to the maximum transmittance, and adjust the reflectivity of the mirror layer 111 to the minimum reflectivity. Also, the at least one processor 120 may control the transparent display layer 112 to display the image (A).

For example, the at least one processor 120 may apply power to the black layer 113, and apply power to the mirror layer 111.

According to an embodiment of the disclosure, light output by the transparent display layer 112 may be transmitted through the mirror layer 111 arranged on the front surface of the transparent display layer 112, and the black layer 113 arranged on the rear surface of the transparent display layer 112.

Unlike in the first operation state and the second operation state according to an embodiment of the disclosure, in the third operation state, the transparent display layer 112 may display the image (A).

The third operation state wherein the transparent display layer 112 displays the image (A) may be divided into a first sub mode and a second sub mode according to the transmittance of the black layer 113. Hereinafter, for the convenience of explanation, the first sub mode of the third operation state will be generally referred to as a transparent effect mode, and the second sub mode of the third operation state will be generally referred to as an image quality improvement mode.

The display device 100 according to an embodiment of the disclosure may further include a sensor. In particular, the sensor may sense external light. However, the disclosure is not limited thereto, and the sensor may sense at least one of various characteristics such as illumination, strength, a color, an incident direction, an incident area, distribution, etc. of light.

Depending on implementation examples, the sensor may become an illumination sensor, a temperature detection sensor, a light quantity sensing layer, a camera, etc.

In particular, the sensor may be implemented as an illumination sensor that senses RGB lights, but is not limited thereto, and any device that can sense light such as a white sensor, an IR sensor, an IR+RED sensor, an HRM sensor, a camera, etc. can be applied.

In this case, the illumination sensor may use several types of photovoltaic cells, but it is possible to use a phototube in measurement of very low illumination. For example, a CDS illumination sensor may be provided on the display device 100 and detect illumination for both directions. In this case, the illumination sensor may be installed in at least one predetermined area of both surfaces of the display device 100, but it can also be installed in each pixel unit of both surfaces. For example, it is possible to install an illumination sensor in a form wherein a CMOS sensor was enlarged to correspond to the size of the mirror display 110, and measure the illumination states of each area or each pixel. For example, a CDS illumination sensor may detect light around the display device 100, and an A/D converter may convert a voltage obtained through the CDS illumination sensor into a digital value, and transmit it to the at least one processor 120.

Meanwhile, at least one sensor may be provided, and in case a plurality of sensors are provided, they can be applied in different directions if they are locations wherein illumination in different directions can be measured. For example, the second sensor may be provided in a location wherein illumination sensing in a different direction that is different from the first sensor by greater than or equal to 90° is possible.

As an example, the sensor may be arranged inside the glass provided on the mirror display 110, and in this case, it may be controlled such that the sensing function can operate normally inside the glass through an algorithm of compensating the transmittance/the reflectivity of the glass provided on the mirror display 110. Other than the above, the display device 100 may further include various sensors necessary for the operations of the display device 100 such as a touch sensor, an acceleration sensor, a geomagnetic sensor, a user detection sensor, etc.

The at least one processor 120 according to an embodiment of the disclosure may adjust the transmittance of the black layer 113 based on light quantity obtained through the sensor.

For example, in the third operation state, if the light quantity obtained through the sensor is greater than or equal to a threshold value, the at least one processor 120 may adjust the transmittance of the black layer 113 from the maximum transmittance to the minimum transmittance.

As an example, the at least one processor 120 may convert the black layer 113 from a clear state to a black state. Alternatively, the at least one processor 120 may convert the black layer 113 from a transparent effect mode to an image quality improvement mode.

For example, if the obtained light quantity (e.g., external light quantity) is high as illustrated in FIG. 9, visibility of the image (A) displayed by the transparent display layer 112 becomes bad due to some of the external light quantity that is transmitted through the black layer 113.

According to an embodiment of the disclosure, in the third operation state, the at least one processor 120 may improve the visibility for the image (A) by blocking (or, absorbing) some light quantity that is transmitted through the black layer 113 by adjusting the transmittance of the black layer 113 to the minimum transmittance.

According to an embodiment of the disclosure, in the third operation state, if the light quantity obtained through the sensor is smaller than the threshold value, the at least one processor 120 may maintain the transmittance of the black layer 113 as the maximum transmittance.

As an example, the at least one processor 120 may maintain the black layer 113 in a clear state. Alternatively, the at least one processor 120 may maintain a transparent effect mode.

For example, if the obtained light quantity is low as illustrated in FIG. 9, visibility of the image (A) displayed by the transparent display layer 112 may not become bad due to some of the external light quantity that is transmitted through the black layer 113.

According to an embodiment of the disclosure, in the third operation state, the at least one processor 120 may provide the image (A) according to the transparent effect mode by maintaining the transmittance of the black layer 113 to the maximum transmittance.

However, this is merely an example, and when the light quantity obtained through the sensor is smaller than the threshold value, the at least one processor 120 can obviously adjust the transmittance of the black layer 113 to the minimum transmittance for improving the visibility of the image (A).

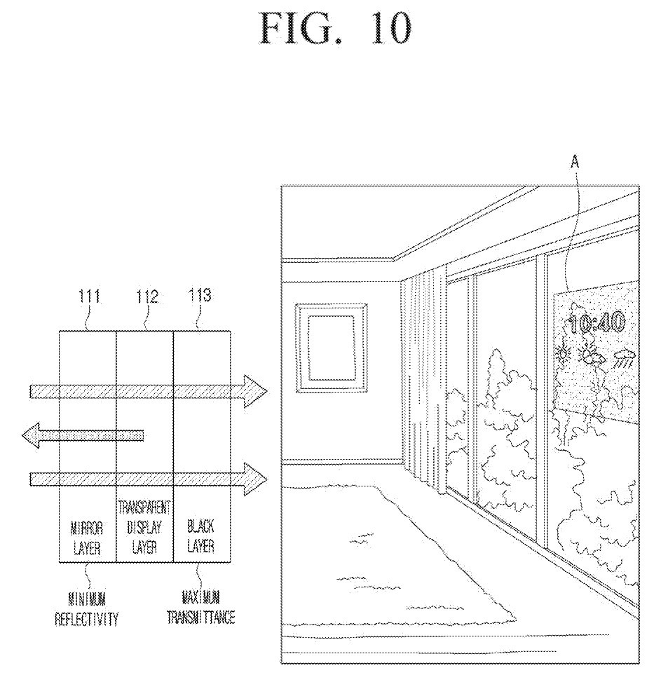

FIG. 10 is a diagram for illustrating an operation state of a display device according to an image according to an embodiment of the disclosure.

Referring to FIG. 10, the at least one processor 120 may identify an image (A) to be displayed through the transparent display layer 112.

According to an embodiment, if the identified image corresponds to a window or a widget, the at least one processor 120 may provide the image (A) according to the transparent effect mode during the third operation state.

For example, the at least one processor 120 may adjust the transmittance of the black layer 113 to the maximum transmittance, and display the image (A) through the transparent display layer 112 in the third operation state.

As an example, if the size of the image (A) corresponds to a partial area of the display area of the transparent display layer 112, the at least one processor 120 may identify that the image (A) corresponds to a window.

As an example, if the location wherein the image (A) is displayed corresponds to a predetermined location inside the display area of the transparent display layer 112, the at least one processor 120 may identify that the image (A) corresponds to a window (or, a widget).

As an example, if the image (A) includes frames of smaller than a predetermined number for provision of information (e.g., weather information, schedule information, traffic information, stock (or, exchange rate) information, etc.), the at least one processor 120 may identify that the image (A) corresponds to a window (or, a widget).

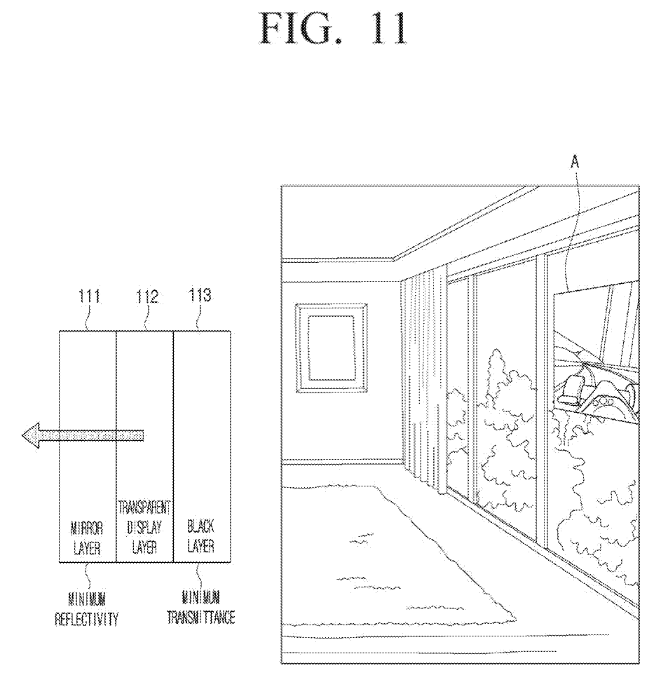

FIG. 11 is a diagram for illustrating an operation state of a display device according to an image according to an embodiment of the disclosure.

Referring to FIG. 11, the at least one processor 120 may identify an image (A) to be displayed through the transparent display layer 112.

According to an embodiment, if the identified image corresponds to a full screen, the at least one processor 120 may provide the image (A) according to the image quality improvement mode during the third operation state.

For example, the at least one processor 120 may adjust the transmittance of the black layer 113 to the minimum transmittance, and display the image (A) through the transparent display layer 112 in the third operation state.

As an example, if the size of the image (A) corresponds to the entire area (or, an area greater than or equal to a predetermined size) of the display area of the transparent display layer 112, the at least one processor 120 may identify that the image (A) corresponds to a full screen.

As an example, if the image (A) is a movie content, a game content, a streaming content, etc. including frames of greater than or equal to a predetermined number, the at least one processor 120 may identify that the image (A) corresponds to a full screen.

However, the disclosure is not limited to the examples illustrated in FIG. 10 and FIG. 11, and the at least one processor 120 can obviously operate in the transparent effect mode or the image quality improvement mode according to various embodiments.

For example, the at least one processor 120 can obviously operate in the transparent effect mode during a predetermined time (e.g., an evening time, a night time), and can operate in the image quality improvement mode during the remaining time (e.g., a daytime).

For example, the at least one processor 120 may obtain mode information corresponding to each of a plurality of applications. According to an embodiment, while displaying any one application among the plurality of applications, the at least one processor 120 may operate in the transparent effect mode or the image quality improvement mode based on the mode information.

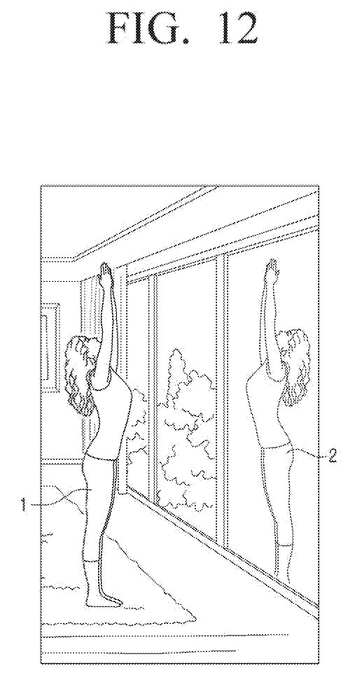

FIG. 12 is a diagram for illustrating an operation state of a display device that detects a user according to an embodiment of the disclosure.

Referring to FIG. 12, if a user 1 is detected within a predetermined distance from the display device 100 through the sensor, the at least one processor 120 may convert the current operation state of the display device 100 to the second operation state.

For example, if the user 1 is located to be adjacent to the display device 100, the at least one processor 120 may adjust the reflectivity of the mirror layer 111 to the maximum reflectivity. As illustrated in FIG. 12, if the reflectivity of the mirror layer 111 is adjusted to the maximum reflectivity, the mirror layer 111 may be maintained in a mirror state that provides a mirror phase 2 corresponding to the user 1 located on the front side of the display device 100.

If a predetermined event is detected, the at least one processor 120 according to an embodiment of the disclosure may convert the current operation state of the display device 100 to the third operation state.

As an example, the predetermined event may include at least one of an event of providing a notification to the user or an event of receiving a user input requesting display of the image (A).

For example, the display device 100 may further include a communication interface. The communication interface can obviously be implemented as various interfaces depending on implementation examples of the display device 100. For example, the communication interface may perform communication with an external device, an external storage medium (e.g., a USB memory), an external server (e.g., a webhard), etc. through communication methods such as Bluetooth, Wi-Fi based on AP (Wi-Fi, a wireless LAN network), Zigbee, a wired/wireless local area network (LAN), a wide area network (WAN), Ethernet, IEEE 1394, a high-definition multimedia interface (HDMI), a universal serial bus (USB), a mobile high-definition link (MHL), Audio Engineering Society/European Broadcasting Union (AES/EBU), optical, coaxial, etc. According to an embodiment, the communication interface may perform communication with another electronic apparatus, an external server, and/or a remote control device, etc.

According to an embodiment, if an event of providing a notification to the user (e.g., reception of a phone call or a text message, etc.) through a user terminal device (e.g., a smartphone) via the communication interface is detected, the at least one processor 120 may convert to the third operation state and control the transparent display layer 112 to provide an image (A) corresponding to the notification.

The at least one processor 120 according to an embodiment may detect a movement of the user through the sensor, and identify (or obtain) a movement value (or, a movement degree) corresponding to the movement of the user.

According to an embodiment, if the movement value is greater than or equal to a threshold value, the at least one processor 120 may convert the current operation state to the second operation state.

For example, if the movement value is greater than or equal to the threshold value, the at least one processor 120 may identify the current situation as a situation wherein the user 1 is exercising, and provision of a mirror phase 2 corresponding to the user 1 is required. According to an embodiment, the at least one processor 120 may maintain the mirror layer 111 in the mirror state that provides the mirror phase 2 corresponding to the user 1 located on the front side of the display device 100.

According to an embodiment, if the movement value is smaller than the threshold value, the at least one processor 120 may convert the current operation state to the third operation state.

For example, if the movement value is smaller than the threshold value, the at least one processor 120 may identify the current situation as a situation wherein the user 1 is sitting on the sofa for watching the image (A), and provision of the image (A) is required. According to an embodiment, the at least one processor 120 may control the transparent display layer 112 to display the image (A).

Meanwhile, the at least one processor 120 can obviously change the current operation state according to a user input for selecting any one of the first to third operation states, or the transparent effect mode or the image quality improvement mode inside the third operation state.

Here, the user input can obviously include a press input for a button provided on a remote control device, a voice input, an input through a viewpoint or a gaze of the user 1, a motion input through a gesture, etc. of the user 1 and the like.

Returning to FIG. 2, the display device 100 includes memory, and the memory may store data necessary for the various embodiments.

The memory 110 may be implemented in a form of memory embedded in the display device 100, or implemented in a form of memory that can be attached to or detached from the display device 100 according to the usage of stored data. For example, in the case of data for driving the display device 100, the data may be stored in memory embedded in the display device 100, and in the case of data for an extended function of the display device 100, the data may be stored in memory that can be attached to or detached from the display device 100. Meanwhile, in the case of memory embedded in the display device 100, the memory may be implemented as at least one of volatile memory (e.g.: dynamic RAM (DRAM), static RAM (SRAM), or synchronous dynamic RAM (SDRAM), etc.) or non-volatile memory (e.g.: one time programmable ROM (OTPROM), programmable ROM (PROM), erasable and programmable ROM (EPROM), electrically erasable and programmable ROM (EEPROM), mask ROM, flash ROM, flash memory (e.g.: NAND flash or NOR flash, etc.), a hard drive, or a solid state drive (SSD)). Also, in the case of memory that can be attached to or detached from the display device 100, the memory may be implemented in forms such as a memory card (e.g., compact flash (CF), secure digital (SD), micro secure digital (Micro-SD), mini secure digital (Mini-SD), extreme digital (xD), a multi-media card (MMC), etc.), and external memory that can be connected to a USB port (e.g., a USB memory), etc.

According to an embodiment, the memory may store at least one instruction or a computer program including instructions for controlling the display device 100.

According to an embodiment, the memory may store contents received from an external device (e.g., a source device), an external storage medium (e.g., a USB), an external server (e.g., a webhard), etc. Alternatively, the memory may store an image obtained through the camera 120 provided on the display device 100.

According to an embodiment, the memory may store various types of information necessary for image quality processing, e.g., information, an algorithm, an image quality parameter, etc. for performing at least one of noise reduction, detail enhancement, tone mapping, contrast enhancement, color enhancement, or frame rate conversion. Also, the memory may store an intermediate image generated by image processing, and an image generated based on depth information.

According to an embodiment, the memory may be implemented as single memory that stores data generated from various operations according to the disclosure. However, according to another embodiment, the memory may also be implemented to include a plurality of memories that store each of different types of data, or store each of data generated in different steps.

Also, the memory may store various types of data, programs, or applications for driving/controlling the display device 100. Other than the above, the memory may include a user sensing module, a communication control module, a voice recognition module, a motion recognition module, a light reception module, a display control module, an audio control module, an external input control module, a power control module, a voice database (DB), or a motion database (DB).

In the aforementioned embodiment, it was explained that various types of data is stored in external memory of the at least one processor 120, but at least some of the aforementioned data can obviously be stored in internal memory of the at least one processor 120.

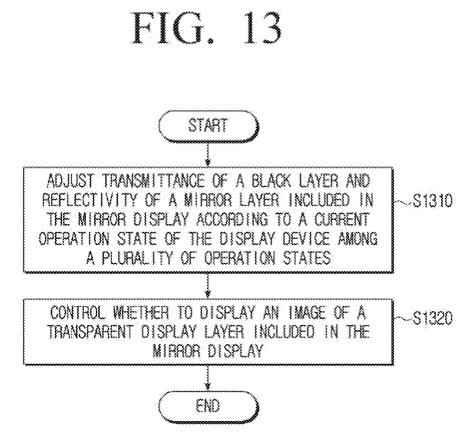

FIG. 13 is a flow chart for illustrating a control method for a display device according to an embodiment of the disclosure.

In a control method for a display device including a mirror display, transmittance of a black layer and reflectivity of a mirror layer included in the mirror display are adjusted according to a current operation state of the display device among a plurality of operation states in the operation S1310.

Then, whether to display an image of a transparent display layer included in the mirror display is controlled in the operation S1320.

The mirror display includes the black layer wherein the transmittance can be adjusted, the transparent display layer which is arranged on a front surface of the black layer and displays the image, and the mirror layer which is arranged on a front surface of the transparent display layer and wherein the reflectivity can be adjusted.

The adjusting operation S1320 according to an embodiment may include the operations of, based on the current operation state being a first operation state, adjusting the transmittance of the black layer to maximum transmittance, and based on the current operation state being the first operation state, adjusting the reflectivity of the mirror layer to minimum reflectivity.

According to an embodiment of the disclosure, based on the transmittance of the black layer being adjusted to the maximum transmittance, the black layer may be in a clear state, and based on the reflectivity of the mirror layer being adjusted to the minimum reflectivity, the mirror layer may be in a clear state.

The adjusting operation S1320 according to an embodiment of the disclosure may include the operations of, based on the current operation state being a second operation state, adjusting the transmittance of the black layer to minimum transmittance, and based on the current operation state being the second operation state, adjusting the reflectivity of the mirror layer to maximum reflectivity, and based on the transmittance of the black layer being adjusted to the minimum transmittance, the black layer may be in a black state, and based on the reflectivity of the mirror layer being adjusted to the maximum reflectivity, the mirror layer may be in a mirror state.

The adjusting operation S1320 according to an embodiment of the disclosure may include the operations of, based on the current operation state being a third operation state, adjusting the transmittance of the black layer to maximum transmittance, and based on the current operation state being the third operation state, adjusting the reflectivity of the mirror layer to minimum reflectivity, and the control method may further include the operation of controlling the transparent display layer to display an image in the third operation state.

The adjusting operation S1320 according to an embodiment of the disclosure may further include the operation of, based on light quantity obtained in the third operation state being greater than or equal to a threshold value, adjusting the transmittance of the black layer from the maximum transmittance to the minimum transmittance.

The control method according to an embodiment of the disclosure may further include the operation of identifying the image for being displayed through the transparent display layer, and the adjusting operation may further include the operations of, based on the identified image corresponding to a window, maintaining the transmittance of the black layer as the maximum transmittance, and based on the identified image corresponding to a full screen, adjusting the transmittance of the black layer from the maximum transmittance to the minimum transmittance.

The control method according to an embodiment of the disclosure may further include the operations of, based on detecting a user within a predetermined distance from the display device, converting the current operation state of the display device to a second operation state, and based on detecting a predetermined event, converting the current operation state to a third operation state, and the predetermined event may include at least one of an event of providing a notification to the user or an event of receiving a user input requesting display of an image.

The control method according to an embodiment of the disclosure may further include the operations of obtaining a movement value of the user, and based on the movement value being greater than or equal to a threshold value, converting the current operation state to the second operation state, and based on the movement value being smaller than the threshold value, converting the current operation state to the third operation state.

The transparent display layer according to an embodiment of the disclosure may include a display panel including self-luminous diodes, or an LCD panel including a backlight, and the arrangement location of the backlight may correspond to an edge method.

Meanwhile, the various embodiments of the disclosure can obviously be applied not only to a display device, but also to various types of electronic apparatuses including a mirror function and a display function.

Meanwhile, the aforementioned various embodiments may be implemented in a recording medium that can be read by a computer or an apparatus similar to a computer, by using software, hardware, or a combination thereof. In some cases, the embodiments described in this specification may be implemented as a processor itself. According to implementation by software, the embodiments such as procedures and functions described in this specification may be implemented as separate software modules. Each of the software modules can perform one or more functions and operations described in this specification.

Meanwhile, computer instructions for performing processing operations of the display device 100 according to the aforementioned various embodiments of the disclosure may be stored in a non-transitory computer-readable medium. Computer instructions stored in such a non-transitory computer-readable medium make the processing operations at the display device 100 according to the aforementioned various embodiments performed by a specific machine, when the instructions are executed by the processor of the specific machine.

A non-transitory computer-readable medium refers to a medium that stores data semi-permanently, and is readable by machines, but not a medium that stores data for a short moment such as a register, a cache, and memory. As specific examples of a non-transitory computer-readable medium, there may be a CD, a DVD, a hard disc, a blue-ray disc, a USB, a memory card, ROM and the like.

While preferred embodiments of the disclosure have been shown and described, the disclosure is not limited to the aforementioned specific embodiments, and it is apparent that various modifications may be made by those having ordinary skill in the technical field to which the disclosure belongs, without departing from the gist of the disclosure as claimed by the appended claims. Further, it is intended that such modifications are not to be interpreted independently from the technical idea or prospect of the disclosure.

1. A display device comprising:
a mirror display including:
a black layer with adjustable transmittance,
a transparent display layer, which is arrangeable on a front surface of the black layer, to display an image, and
a mirror layer, which is arrangeable on a front surface of the transparent display layer, with adjustable reflectivity; and
at least one processor configured to:
adjust the transmittance of the black layer and the reflectively of the mirror layer according to a current operation state of the display device among a plurality of operation states of the display device, and
control whether to display the image through the transparent display layer.

2. The display device of claim 1,
wherein the at least one processor is configured to:
based on the current operation state, adjust the transmittance of the black layer to a maximum transmittance, and adjust the reflectivity of the mirror layer to a minimum reflectivity.

3. The display device of claim 2,
wherein, based on the transmittance of the black layer being adjusted to the maximum transmittance, the black layer is in a clear state, and
based on the reflectivity of the mirror layer being adjusted to the minimum reflectivity, the mirror layer is in a clear state.

4. The display device of claim 1,
wherein the at least one processor is configured to:
based on the current operation state, adjust the transmittance of the black layer to a minimum transmittance, and adjust the reflectivity of the mirror layer to a maximum reflectivity, and
based on the transmittance of the black layer being adjusted to the minimum transmittance, the black layer is in a black state, and
based on the reflectivity of the mirror layer being adjusted to the maximum reflectivity, the mirror layer is in a mirror state.

5. The display device of claim 1,
wherein the at least one processor is configured to:
based on the current operation state, adjust the transmittance of the black layer to a maximum transmittance, and adjust the reflectivity of the mirror layer to a minimum reflectivity, and
control the transparent display layer to display the image.

6. The display device of claim 5, further comprising:
a sensor,
wherein the at least one processor is configured to:
based on light quantity obtained through the sensor in the current operation state being greater than or equal to a threshold value, adjust the transmittance of the black layer from the maximum transmittance to the minimum transmittance.

7. The display device of claim 5,
wherein the at least one processor is configured to:
identify the image being displayed through the transparent display layer,
based on the identified image corresponding to a window, maintain the transmittance of the black layer as the maximum transmittance, and
based on the identified image corresponding to a full screen, adjust the transmittance of the black layer from the maximum transmittance to a minimum transmittance.

8. The display device of claim 1, wherein the current operation state is a first operation state, and the display device further comprises:
a sensor,
wherein the at least one processor is configured to:
based on detecting a user within a predetermined distance from the display device through the sensor, change the first operation state of the display device to a second operation state,
based on detecting a predetermined event, change the current operation state to a third operation state, and
the predetermined event comprises:
at least one of an event of providing a notification to the user or an event of receiving a user input requesting display of an image.

9. The display device of claim 8,
wherein the at least one processor is configured to:
obtain a movement value of the user through the sensor,
based on the movement value being greater than or equal to a threshold value, convert the current operation state to the second operation state, and
based on the movement value being smaller than the threshold value, convert the current operation state to the third operation state.

10. The display device of claim 1,
wherein the transparent display layer comprises:
a display panel including self-luminous diodes, or an LCD panel including a backlight, and
an arrangement location of the backlight corresponds to an edge type.

11. A control method for a display device including a mirror display, the control method comprising:
adjusting transmittance of a black layer and reflectivity of a mirror layer included in the mirror display according to a current operation state of the display device among a plurality of operation states; and
controlling whether to display an image through a transparent display layer included in the mirror display,
wherein the mirror display comprises:
the black layer with the transmittance that is adjustable, the transparent display layer, which is arrangeable on a front surface of the black layer, to display the image, and the mirror layer, which is arrangeable on a front surface of the transparent display layer, and with the reflectivity that is adjustable.

12. The control method of claim 11,
wherein the adjusting comprises:
based on the current operation state, adjusting the transmittance of the black layer to a maximum transmittance; and
based on the current operation state being the first operation state, adjusting the reflectivity of the mirror layer to a minimum reflectivity.

13. The control method of claim 12,
wherein, based on the transmittance of the black layer being adjusted to the maximum transmittance, the black layer is in a clear state, and
based on the reflectivity of the mirror layer being adjusted to the minimum reflectivity, the mirror layer is in a clear state.

14. The control method of claim 11,
wherein the adjusting comprises:
based on the current operation state, adjusting the transmittance of the black layer to a minimum transmittance; and
based on the current operation state, adjusting the reflectivity of the mirror layer to a maximum reflectivity, and
based on the transmittance of the black layer being adjusted to the minimum transmittance, the black layer is in a black state, and
based on the reflectivity of the mirror layer being adjusted to the maximum reflectivity, the mirror layer is in a mirror state.

15. The control method of claim 11,
wherein the adjusting comprises:
based on the current operation state, adjusting the transmittance of the black layer to a maximum transmittance; and
based on the current operation state, adjusting the reflectivity of the mirror layer to a minimum reflectivity, and
the control method further comprises:
controlling the transparent display layer to display an image in the third operation state.

16. The control method of claim 15,
wherein the adjusting comprises:
based on light quantity obtained in the current operation state being greater than or equal to a threshold value, adjusting the transmittance of the black layer from the maximum transmittance to the minimum transmittance.

17. The control method of claim 15,
wherein the control method further comprises:
identifying the image being displayed through the transparent display layer; and
wherein the adjusting comprises:
based on the identified image corresponding to a window, maintaining the transmittance of the black layer as the maximum transmittance; and
based on the identified image corresponding to a full screen, adjusting the transmittance of the black layer from the maximum transmittance to a minimum transmittance.

18. The control method of claim 11,
wherein the current operation state is a first operation state, and the control method further comprises:
based on detecting a user within a predetermined distance from the display device through the sensor, changing the first operation state of the display device to a second operation state; and
based on detecting a predetermined event, changing the current operation state to a third operation state; and
the predetermined event comprises:
at least one of an event of providing a notification to the user or an event of receiving a user input requesting display of an image.

19. The control method of claim 18,
wherein the control method further comprises:
obtaining a movement value of the user;
based on the movement value being greater than or equal to a threshold value, changing the current operation state to the second operation state; and
based on the movement value being smaller than the threshold value, changing the current operation state to the third operation state.

20. The control method of claim 11,
wherein the transparent display layer comprises:
a display panel including self-luminous diodes, or an LCD panel including a backlight, and
an arrangement location of the backlight corresponds to an edge type.
